(19) United States
(12) Patent Application Publication
(10) Pub. No.: US 2003/0186078 A1
(43) Pub. Date: Oct. 2, 2003

(54) RGB patterning of organic light-emitting devices using photo-bleachable emitters dispersed in a common host

(76) Inventors: Hideyuki Murata, Surrey (GB); Lisa C. Picciolo, Silver Spring, MD (US); Zakya H. Kafafi, Alexandria, VA (US)

Correspondence Address: NAVAL RESEARCH LABORATORY, ASSOCIATE COUNSEL (PATENTS), CODE 1008.2, 4555 OVERLOOK AVENUE, S.W., WASHINGTON, DC, 20375-5320, US

(21) Appl. No.: 10/113,648

(22) Filed: Mar. 29, 2002

(51) Int. Cl. H05B 33/14; H05B 33/10

(52) U.S. Cl. 428/690; 428/917; 428/201; 313/504; 313/506; 427/66; 257/89

(57) ABSTRACT

The present invention provides a method for fabricating an electroluminescent EL display, wherein the individual color pixels are formed by doping a common blue-emitting host with two or more photo-bleachable (or photo-oxidizable) dopants, such as red and green emitting organic materials. The host may also be doped with a blue emitting material that is not photo-bleachable.

### BACKGROUND OF THE INVENTION

1. Field of the Invention

This invention relates to electroluminescent (EL) devices and, more specifically, to organic EL materials and a process for the fabrication of multi-color organic EL devices for flat panel display applications.

2. Description of the Background Art

Organic EL devices also referred to as organic light emitting devices (OLEDs) are an emerging technology that may soon replace liquid crystal displays (LCDs) in flat panel display applications due to their desirable characteristics including self-emissive high brightness, wide viewing angles, light-weight, and low power consumption. Recently, Sony previewed a prototype of an OLED-based display (13″ diagonal) that is slightly thicker than a credit card. A display is made up of many tiny individual pixels (picture elements). An OLED represents one pixel. In a full-color display, each pixel contains one or all of the three color components: red, green and blue (RGB).

An OLED generally consists of the following elements: a transparent substrate, typically glass or plastic, coated with a transparent conducting material; one or more hole injecting and/or hole transporting layers (HTL); one or more electron transporting (ETL) and/or electron injecting layers; and a cathode made up of low work function metals. The HTL or ETL may also have light emissive properties or a separate emitting layer may be sandwiched between the HTL and ETL.

Developing efficient and economical methods to manufacture RGB patterned pixels is one of the main issues concerning the realization of full-color flat panel displays. Several approaches have been developed to achieve full-color organic emissive displays. The first method consists of filtering white light with RGB band-pass filters. This technique results in a large reduction of the optical power from the white OLED. Thus the color-filtered OLEDs must be operated at high brightness/current density with increased power consumption, which may accelerate degradation and shorten the lifetime of the device.

Another method utilizes the conversion of blue light to green light and red light through a color converting layer comprising a fluorescent material and has been demonstrated with many variations (See U.S. Pat. Nos. 5,126,214; 5,294,870; 6,019,654; 6,023,371; 6,137,221; 6,249,372, all herein incorporated by reference). A major challenge of this method is the difficulty of finding a red fluorescent material with a high absorption coefficient in the blue wavelength region and having a high fluorescence in the red wavelength region. This method also results in reduced device efficiency during the color conversion process.

Yet another method used to achieve RGB emission is through the patterning of discrete RGB sub-pixels as shown in FIG. 1. This method has been demonstrated with the use of precise shadow masks (See U.S. Pat. No. 6,214,631, herein incorporated by reference) and with a laser ablation technique (See U.S. Pat. No. 6,146,715, herein incorporated by reference). The laser ablation technique is used to etch away undesired organic and electrode layers to avoid using harsh photoresist chemicals to pattern discrete RGB pixels adjacent to each other on the same substrate. This approach is more advantageous than the others because the red, green, and blue OLEDs are individually optimized to achieve high device efficiencies at low power. Typically, three different LED structures are used in order to optimize each color pixel, with a minimum of two different materials (host and dopant) for each of the primary colors.

The doping of fluorescent materials into organic host materials has been shown to be an effective approach for achieving color tunability (See Shoustikov, et al., IEEE Journal of Selected. Topics in Quantum Electronics., vol. 4, p.3, 1998, herein incorporated by reference), as well as improving device efficiency (See Tang, Information Display, vol. 12, p.16, 1996, herein incorporated by reference), and durability (See Shi, et al., Applied Physics Letters, vol. 70, p.1665, 1997, herein incorporated by reference).

Organic electroluminescent devices that include organic host materials and dopants are disclosed, for example, in the following patents and publications, all herein incorporated by reference: U.S. Pat. No. 3,172,862 to Gurnee, et al.; U.S. Pat. No. 3,173,050 to Gurnee; U.S. Pat. No. 3,710,167 to Dresner, et al.; U.S. Pat. No. 4,356,429 to Tang; U.S. Pat. No. 4,769,292 to Tang, et al.; U.S. Pat. No. 5,059,863; U.S. Pat. No. 5,126,214 to Tokailin, et al.; U.S. Pat. No. 5,382,477 to Saito, et al.; U.S. Pat. No. 5,409,783 to Tang, et al.; U.S. Pat. No. 5,554,450 to Shi, et al.; U.S. Pat. No. 5,635,307 to Takeuchi, et al.; U.S. Pat. No. 5,674,597 to Fujii, et al.; U.S. Pat. No. 5,709,959 to Adachi, et al.; U.S. Pat. No. 5,747,183 to Shi, et al.; U.S. Pat. No. 5,756,224 to Borner, et al.; U.S. Pat. No. 5,861,219 to Thompson, et al.; U.S. Pat. No. 5,908,581 to Chen, et al.; U.S. Pat. No. 5,932,363 to Hu, et al.; U.S. Pat. No. 5,935,720 to Chen, et al.; U.S. Pat. No. 5,935,721 to Shi, et al.; U.S. Pat. No. 5,948,941 to Tamano, et al.; U.S. Pat. No. 5,989,737 to Xie, et al.; International Publication No. WO 98/06242 (Forrest et al.); C. W. Tang, et al. “Electroluminescence of Doped Organic Thin Films”, J. Appl. Phys., 65(9), May 1969, pp 3610-3616; C. W. Tang and S. A. VanSlyke, “Organic Electroluminescent Diodes”, Appl. Phys. Letters, 51(12), Sept. 21, 1987, pp. 913-915; Baldo, et al., “Highly Efficient Phosphorescent Emission from Organic Electroluminescent Devices”, Nature, Vol. 395, Sep. 10, 1998, pp 151-153; O'Brien, et al. “Improved Energy Transfer in Electrophosphorescent Devices”, Applied Physics Letters, Vol. 74, No. 3, Jan. 18, 1999, pp. 442-444.

FIG. 1 is an illustration of a typical OLED structure utilizing three individually optimized color pixels (RGB) as described in the prior art. The transparent substrate 100 is patterned with the first electrode a transparent conducting oxide such as indium tin oxide 101. This is followed by a hole transporting layer 102. An organic EL layer is then formed for each individual color pixel: red emitting dopant and host 103; green emitting dopant and host 104 and blue emitting host and dopant 105. This layer is followed by one or more electron injecting/transporting layers 106. Stripes orthogonal to the first electrode are patterned to form the second electrode 107, typically a low work function metal. 108 represents an encapsulation layer.

The prior art methods have numerous drawbacks that lead to poor efficiency and brightness. The best method involves complicated devices structures using numerous organic materials for each color pixel, which increases the fabrication steps and production costs.

### BRIEF SUMMARY OF THE INVENTION

This invention discloses an alternative approach to fabricating organic EL displays with simplified LED structures, a minimal number of materials, and leads to RGB color in a minimum number of steps.

The present invention provides a method for fabricating an EL display, wherein the individual color pixels are formed by doping a common blue-emitting host with two or more photo-bleachable (or photo-oxidizable) dopants, such as red and green emitting organic materials. The host may also be doped with a blue emitting material that is not photo-bleachable. The concept of using a dopant to convert emission from one wavelength region to another via photo-oxidation has been used in the patterning of yellow, blue and yellow, green pixels for OLEDs using the photo-bleachable yellow emitter, rubrene ( see J. Kido, Y. Yamagata, and G. Harada, Sen-I Gakkai Symposium Preprints, S-39 (1997) and J. Kido, S. Shirai, Y. Yamagata and G. Harada, MRS Spring Conference (1998)). Light at wavelengths corresponding or near the maximum absorption peaks of the guest materials to be photo-bleached is irradiated onto the surface of the material in the presence of oxygen for an adequate time period. The combination of light and oxygen bleaches the desired emitting species rendering it non-emissive. As a result, emission will occur from the longest wavelength still present in the layer. For example, if the red emitting material was photo-bleached, then emission will result from the next longest wavelength material, which is the green emitting material. Similarly this process can be carried out on both the green and red emitting materials resulting in emission from only the blue emitting material.

The combination of photo-bleachable fluorescent or phosphorescent materials with a common host leads to a simple and cost efficient method for patterning RGB pixels and can reduce cross contamination and processing steps in patterning of RGB EL displays.

The present invention may be achieved in whole or in part by a method of fabricating an organic EL display, comprising the following steps: (1) the device is constructed on a transparent glass or plastic substrate patterned with a first electrode that is transparent to light; (2) providing one or more hole injecting and/or transporting layers; (3) providing an organic EL layer, comprised of a blue emitting host material doped with photo-bleachable green and red organic dopants (and possibly a non-photo-bleachable blue emitting material) sandwiched between first and second electrodes; and (4) creating individual color pixels by partial irradiation, in the presence of oxygen, with light at one or more wavelengths corresponding or near the maximum absorption peaks of the guest materials to be photo-bleached (i.e. red and green; λ₁,λ₂). For example, the organic EL layer is initially irradiated with both wavelengths of light (λ₁,λ₂) which photo-bleaches the two guest emitters resulting in blue emission from a third guest emitter or a blue-emitting common host. Next, the green emitting pixel is created by irradiating the film with light corresponding to λ₁ in the presence of oxygen to photo-bleach the red guest emitter. In order to prevent degradation of the green guest emitter, λ₁ should be long enough to be absorbed only by the red emitter. The remaining active area of the device that has not been irradiated produces the red color pixel. (5) providing one or more electron injecting and/or electron transporting layers; (6) providing a second electrode in contact with the electron injecting/transporting layer; (7) providing an encapsulation structure to keep oxygen and water out of the device.

The present invention may also be achieved in whole or in part by a method of fabricating an organic EL display as stated previously, where the common blue emitting host material has either electron or hole transport layers and may be used undoped as a separate electron or hole transport layer.

The present invention may also be achieved in whole or in part by a method of fabricating an organic EL display as stated previously where the creation of the color pixels is carried out with or without the use of a mask.

Additional advantages, objects, and features of the invention will be set forth in part in the description which follows and in part will become apparent to those having ordinary skill in the art upon examination of the following or may be learned from practice of the invention.

### BRIEF DESCRIPTION OF THE DRAWINGS

FIG. 1 is a cross-sectional view of an OLED.

FIG. 2A is a cross-sectional view of an organic EL display prior to the photo-bleaching technique, in accordance with the present invention.

FIG. 2B illustrates the photo-bleaching technique to achieve a blue color pixel, in accordance with the present invention.

FIG. 2C illustrates the photo-bleaching technique to achieve a green color pixel, in accordance with the present invention.

FIG. 3 illustrates the present invention's photo-bleaching technique using a mask.

FIG. 4 represents the RGB color pixels and emission achieved after photo-bleaching process and remaining device fabrication is complete and a bias is applied.

FIG. 5A is an example of the photoluminescence (PL) spectra achieved using photo-bleachable red and greed emitting materials doped into a blue emitting host material.

FIG. 5B is an example of the chromaticity coordinates, plotted on a color gamut, achieved using photo-bleachable red and greed emitting materials doped into a blue emitting host material.

FIG. 6 is the PL spectra of photo-bleachable red emitting species doped into a blue emitting host as it is photo-bleached with a light source in the presence of oxygen. The intensity of the red emitting species (at wavelengths longer than 580 nm) begins to decrease and the intensity of the blue emitting species begins to increase as the film is photo-bleached.

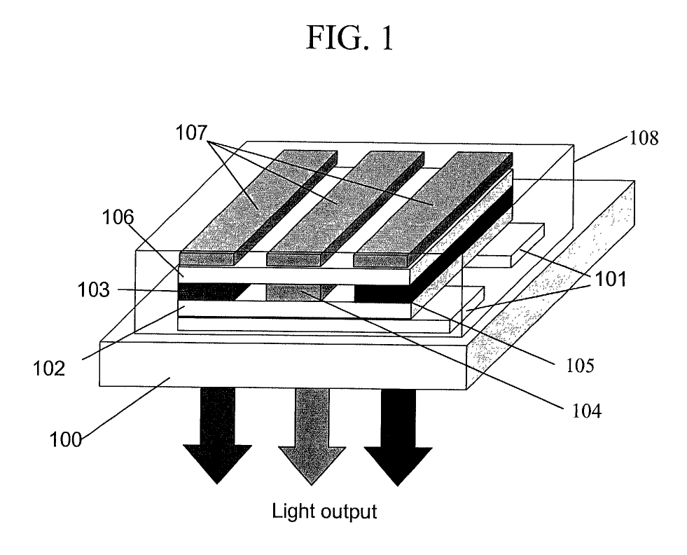

### DETAILED DESCRIPTION OF THE INVENTION AND PREFERRED EMBODIMENTS

For the fabrication of an organic EL display that has RGB color pixels sandwiched between two electrodes, the present invention utilizes a patterning method that: (1) employs a common blue emitting host material for all of the dopant emitting materials (note: dopant emitting materials can be either fluorescent or phosphorescent); (2) employs red and green dopants that are photo-bleachable, that is, they become non-emissive under a combination of the appropriate light source and oxygen; (3) may employ an additional blue emitting dopant that is not photo-bleachable; (4) may or may not use a mask during the photo-bleaching process; (5) minimizes the number of organic materials used; (6) minimizes the number of processing steps necessary for patterning the organic EL layer, thus simplifying the device structure; (7) reduces the risk of cross contamination; and (8) significantly reduces the costs of fabricating an organic EL display.

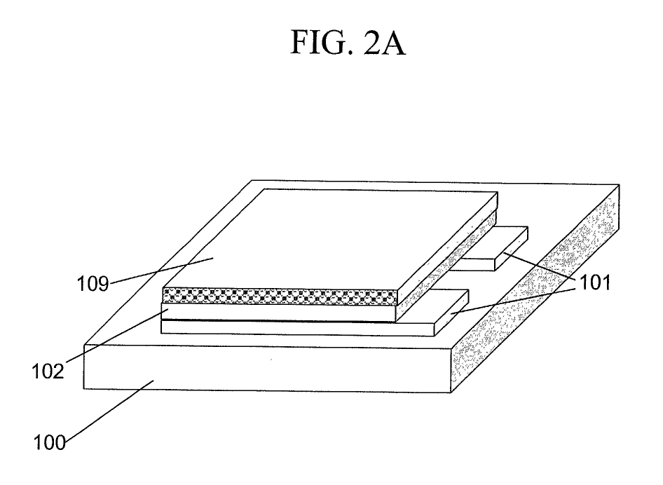

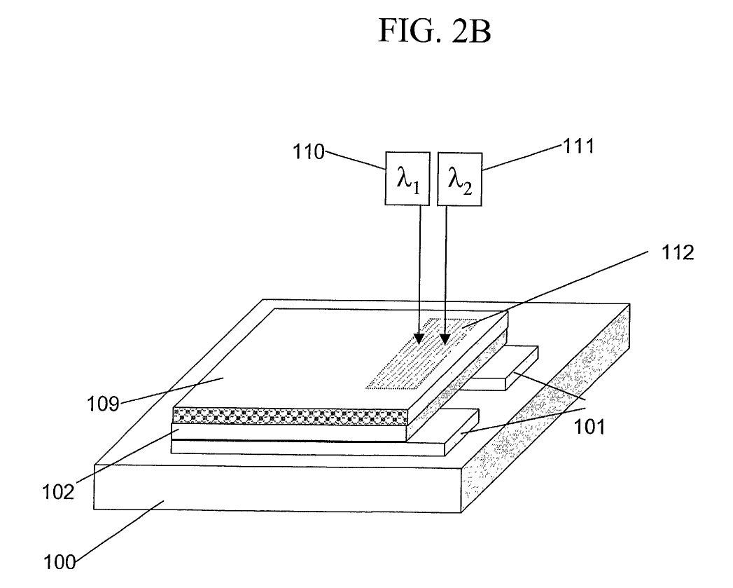

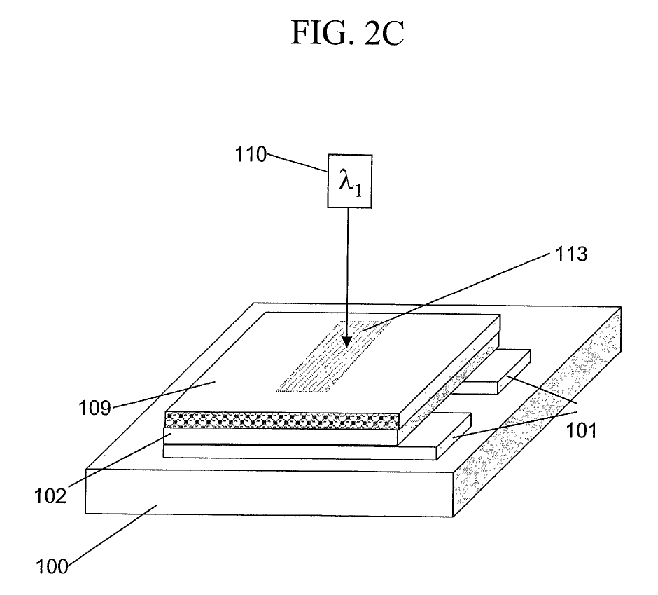

FIGS. 2A-D and 3 are illustrations of the photo-bleaching technique, in accordance with the present invention. Referring to FIG. 2A, after the first patterned electrode 101 is formed on the substrate 100, a hole injecting/transporting material 102 is deposited adjacent and is the same for all of the individual color pixels. The organic EL layer 109, containing a common blue emitting host material doped with photo-bleachable red and green emitting materials and possibly a non-photo-bleachable blue emitting material, is deposited next. As previously stated, these emitting materials may be either fluorescent or phosphorescent. FIG. 2B illustrates the photo-bleaching technique to achieve a blue color pixel, in accordance with the present invention. The organic EL layer 109 is partially irradiated, in the presence of oxygen, with light at wavelengths (λ₁,λ₂) 110 corresponding or near the maximum absorption peaks of the red and green guest materials (ex: pentacene (λ₁) and anthracene (λ₂) derivatives). The two wavelengths of light (λ₁ 110) and (λ₂ 111) photo-bleach the red and green emitting materials resulting in a blue color pixel 112 where the blue emission is from a third blue emitter or a blue-emitting common host (ex: 5,5′-bis(dimesitylboryl)-2,2′-bithiophene (BMB-2T)). FIG. 2C illustrates the photo-bleaching technique to achieve a green color pixel, in accordance with the present invention. The organic EL layer 109 is partially irradiated in a location where the green color pixel is desired. The organic EL layer 109 is irradiated with light λ₁ 110 corresponding or near the maximum absorption peak of the red emitting material in the presence of oxygen. This process photo-bleaches the red guest emitter (ex: pentacene derivative) and results in a green color pixel 113 from the green emitting material (ex: anthracene derivative). In order to prevent degradation of the green emitting material, λ₁ 110 should be long enough to be absorbed only by the red emitter.

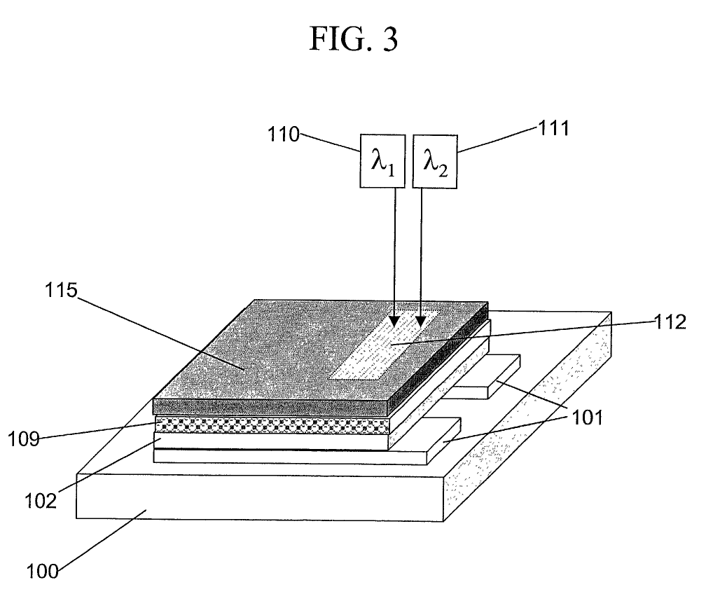

The present invention may also be carried out using a mask 115 during the photo-bleaching technique. This technique is similar to the previous description but with a mask in place that can be used as a template for the light sources. FIG. 3 illustrates the photo-bleaching technique using a mask, in accordance with the present invention. The organic EL layer 109 is partially irradiated through a mask 115, in the presence of oxygen, with light at wavelengths (λ₁,λ₂) 110 corresponding or near the maximum absorption peaks of the red and green guest materials (ex: pentacene (λ₁) and anthracene (λ₂) derivatives). The two wavelengths of light (λ₁ 110) and (λ₂ 111) photo-bleach the red and green emitting materials resulting in a blue color pixel 112 where the blue emission is from a third blue emitter or a blue-emitting common host (ex: 5,5′-bis(dimesitylboryl)-2,2′-bithiophene (BMB-2T)). The mask is shifted or changed in order to perform the photo-bleaching technique for the green color pixel in the same manner as described when a mask is not used.

Again, dopant materials can be selected from either fluorescent or phosphorescent emitters. The present invention, as described herein, employs the use of fluorescent emitters. However, phosphorescent emitters have been used extensively for red and green emitting OLEDs and may be highly suitable for use in photo-bleaching techniques. Examples of red and green phosphorescent emitters that may be employed in photo-bleaching are 2,3,7,8,12,13,17,18-octaethyl-21H,23H-porphine platinum (II) (PtOEP) and tris(2-phenylpyridine)iridium (Irppy3), respectively.

After removal of the oxygen from the film by slight heating and/or pumping on it under vacuum, device fabrication is completed with the deposition of one or more electron injection/transport layers 106, the second electrode 107, and the encapsulation layer 108. Upon an applied voltage, the device emits RGB light through the transparent substrate 100. Red and green emission can be the result of efficient energy transfer from host to guest and/or direct carrier recombination on the red and green-emitting guest molecules. Blue emission may arise from direct electron-hole recombination on a blue-emitting guest or on the common host where the red and green emitting guests were rendered non-emissive due to photo-oxidation.

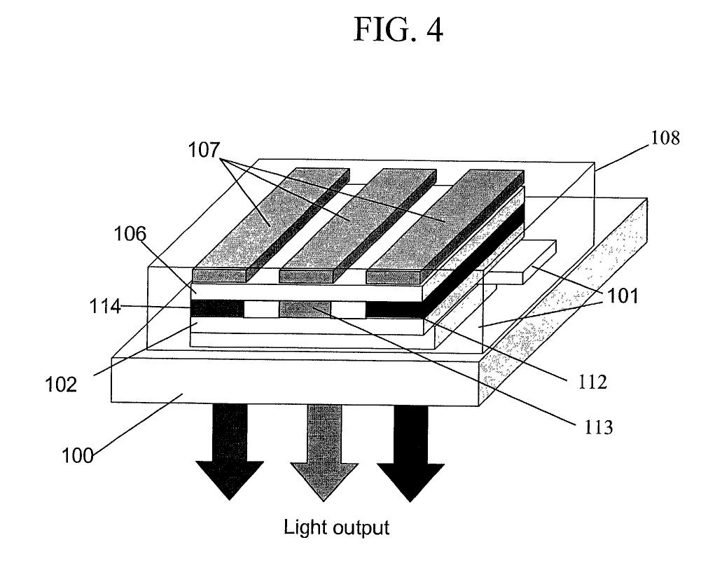

FIG. 4 represents the RGB color pixels and emission achieved after photo-bleaching process and remainder of device fabrication is complete and a bias is applied. The red color pixel 114 will appear in the organic EL layer where the photo-bleaching process has not been performed and is defined by the first and second electrodes 101 and 107. Emission from the emitting material with the longest wavelength (red emitting material) will naturally occur when a mixture of emitting dopants are present.

One difference between the prior art and the present invention is that the present invention utilizes the same organic EL layer 109 for all of the color pixels and with the application of the photo-bleaching technique can obtain individual RGB color pixels from that same layer. The advantage of the present invention over prior art is that is reduces the number of different organic materials, which greatly reduces the risk of cross contamination that occurs when individual color pixels are created with techniques of prior art. Another advantage to the use of a single organic EL layer 109 is that it reduces the fabrication costs and thus the overall costs of the organic EL display which drives their marketability in the flat panel display market.

A new feature of the present invention is the use of a common host for red-emitting and green-emitting materials with photo-bleaching characteristics necessary for tuning red to green to blue emission for patterned OLEDs.

This approach offers a simple and cost-effective technique to achieve patterned red, green, and blue (RGB) organic light emitting devices (OLEDs) by taking advantage of the photo-oxidative properties of organic dyes such as polyaromatic hydrocarbons.

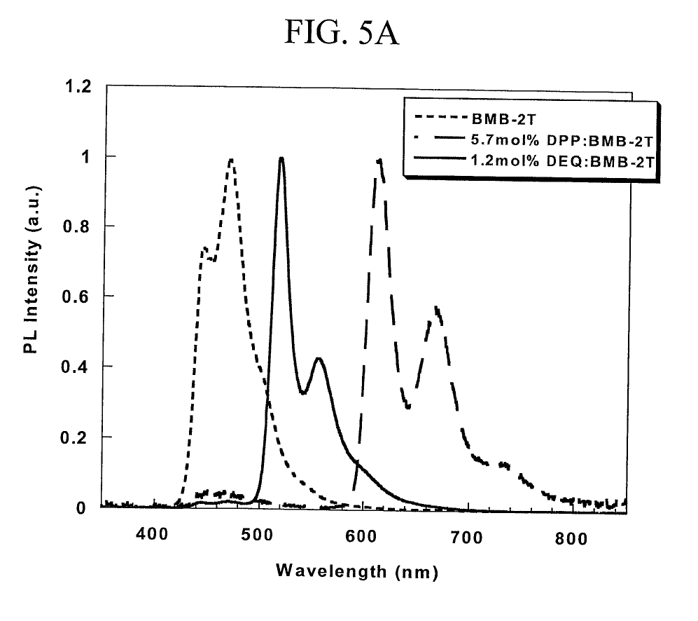

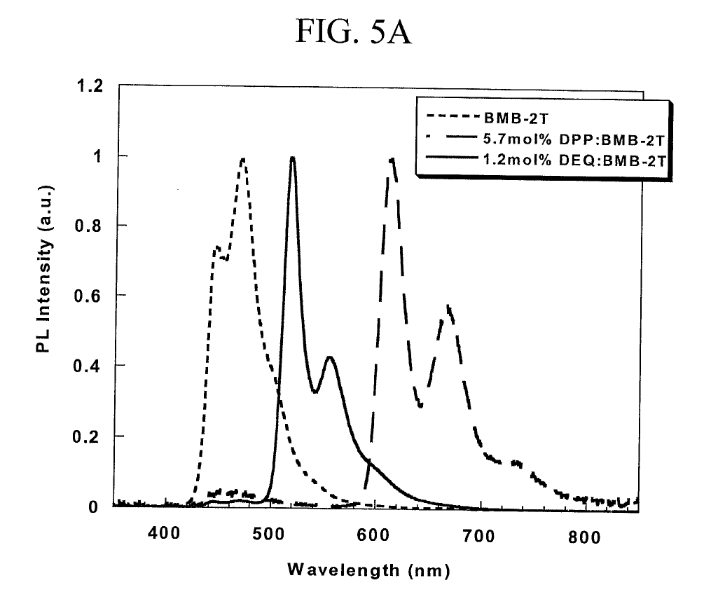

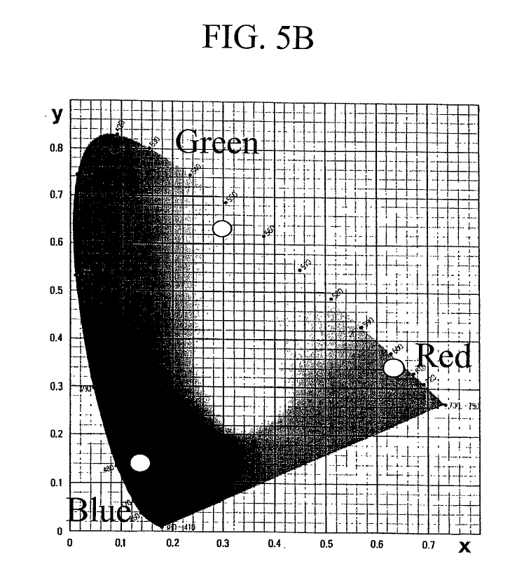

An example of a RGB photo-bleachable organic EL layer is the red emitting material, 6,13-diphenylpentacene (DPP), (see L. C. Picciolo, H. Murata, and Z. H. Kafafi, Applied Physics Letters, vol. 78, p. 2378, 2001) and the green guest emitter, diethylquinacridone (DEQ) (see H. Murata, C. D. Merritt, H. Inada, Y. Shirota, and Z. H. Kafafi, Applied Physics Letters, vol. 75, p.3252, 1999), doped into the blue-emitting common host BMB-2T (see T. Noda and Y. Shirota, Advanced Materials, vol. 11, p.283, 1999). DPP and DEQ are photo-bleachable with the appropriate light sources. The emission spectra of DPP, DEQ and BMB-2T are shown in FIG. 5A. The Commission Internationale de L'Eclairage (CIE) chromaticity coordinates of these materials are shown on a color gamut in FIG. 5B.

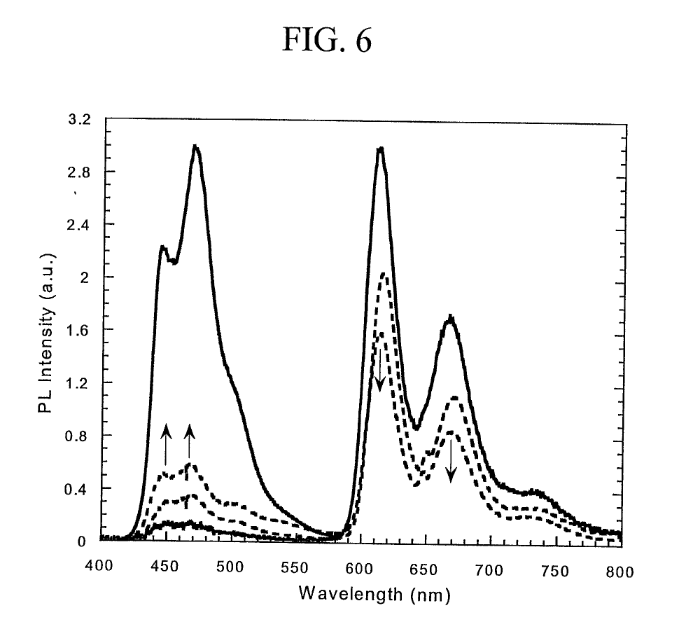

FIG. 6 is the PL spectra of the photo-bleachable red emitting species DPP doped into a blue emitting host BMB-2T before and during photo-bleaching with a light source, matched with the absorption of the red emitting species, in the presence of oxygen. Initially, the spectrum is dominated by red emission from the red emitting species DPP (at wavelengths longer than 580 nm). Upon irradiation, the DPP peaks start to decrease, due to photo-bleaching, with the concomitant growth of the BMB-2T peaks (wavelengths 450 and 470 nm), which give rise to blue emission when DPP is totally photo-bleached.

The layers described in the present invention are deposited through a method referred to as vacuum deposition, but the present invention may also be carried out using wet techniques such as spin coating for one ore more of the layers.

The light sources 110-111 of appropriate wavelengths should be selected, based on the physical and chemical properties of the materials to be photo-bleached. An important factor is the absorption maxima of the material as a function of wavelength. The wavelength of one light source should be matched with only the absorption maxima of the dopant that is currently being photo-bleached. The combination of two light sources 110-111 should be administered to photo-bleach two emitting dopants. None of the light sources chosen should match the absorption wavelengths of the blue emitting materials, host or dopant. The power of the light source and the length of time it is directed at the organic EL layer 109 should be optimized so as not to damage other layers by creating localized heating. The shape and size of the light source may be adjusted as required.

The present invention may be carried out by changing the motion of the light sources or the substrate in order to create the desired color pixel shape and pattern.

We claim:

1. An organic light emitting diode (OLED), comprising:
an organic electroluminescent (EL) layer;
a hole transporting layer;
an electron transport layer;
wherein said organic EL layer comprises a common blue emitting host material doped with red and green emitting materials, at least one of which has been photo-bleached;
wherein said hole transporting layer and said electron transport layer are on opposing sides of said common host, and are in electrical contact with said common host;
wherein said hole transporting layer, said electron transport layer, and said common host together comprise an active portion of said OLED;
electrodes on opposing sides of said active portion for providing a bias across said active portion;
wherein at least one of said electrodes is transparent.

2. The OLED of claim 1, wherein said organic EL layer is additionally doped with a blue emitting material that is not photo-bleachable.

3. The OLED of claim 1, wherein said blue emitting host material is 5,5′-bis(dimesitylboryl)-2,2′-bithiophene.

4. The OLED of claim 1, wherein said red emitting materials is 6,13-diphenylpentacene.

5. The OLED of claim 1, wherein said green emitting material is N,N′-diethylquinacridone.

6. The OLED of claim 1, wherein said blue emitting host material is a material adapted to emit at wavelengths in the blue visible light region or shorter.

7. The OLED of claim 1, wherein said hole transporting layer is 4,4-bis(1-naphthylphenylamino)biphenyl.

8. The OLED of claim 1, wherein said electron transport layer is 5,5′-bis(dimesitylboryl)-2,2′-bithiophene.

9. The OLED of claim 1, wherein at least one of said transparent electrodes comprises a glass substrate coated with a transparent anode material.

10. The OLED of claim 9, wherein said transparent anode material is indium tin oxide.

11. The OLED of claim 1, wherein one of said electrodes comprises a metallic cathode.

12. The OLED of claim 1, wherein said metallic cathode comprises an alloy of Mg and Ag.

13. A method of making an OLED, comprising the steps of:
(1) forming a first patterned electrode having a top and bottom side onto a transparent substrate having a top and bottom side, wherein said first patterned electrode bottom side is in electrical contact with said transparent substrate top side;
(2) depositing a hole transporting layer having a top and bottom side onto said first patterned electrode, wherein said hole transporting layer bottom side is in electrical contact with said first patterned electrode top side;
(3) depositing an organic EL layer, comprising a common blue emitting host material doped with red and green emitting materials, having a top and bottom side onto said hole transporting layer, wherein said organic EL layer bottom side is in electrical contact with said hole transporting layer top side;
(4) irradiating, in the presence of oxygen, a selected portion A of said organic EL layer with light at two wavelengths selected to photo-bleach each of said red and green emitting materials of said selected portion A, resulting in a blue color pixel in said selected portion A of said organic EL layer;
(5) irradiating, in the presence of oxygen, a selected portion B of said organic EL layer with light at a wavelength selected to photo-bleach said red emitting material of said selected portion B, resulting in a green color pixel in said selected portion B of said organic EL layer;
wherein said irradiating steps 4 and 5 leave a selected portion C of said organic EL layer unphotobleached;
(6) removal of residual oxygen from said organic EL layer by application of slight heating or vacuum;
(7) depositing an electron transport layer having a top and bottom side onto said organic EL layer, wherein said electron transport layer bottom side is in electrical contact with said organic EL layer top side;
(8) depositing a second patterned electrode having a top and bottom side onto said electron transport layer, wherein said second patterned electrode bottom side is in electrical contact with said electron transport layer top side; and
(9) encapsulation of entire said OLED with an encapsulating agent.

14. The method of claim 13, wherein said irradiating step 4 and 5 are conducted through a mask resulting in irradiation of only predetermined sections of said organic EL layer.

15. The method of claim 13, wherein said organic EL layer is additionally doped with a blue emitting material that is not photo-bleachable.

16. The method of claim 13, wherein said blue emitting host material is 5,5′-bis(dimesitylboryl)-2,2′-bithiophene.

17. The method of claim 13, wherein said red emitting material is 6,13-diphenylpentacene.

18. The method of claim 13, wherein said green emitting material is N,N′-diethylquinacridone.

19. The method of claim 13, wherein said blue emitting host material is a material adapted to emit at wavelengths in the blue visible light region or shorter.

20. The method of claim 13, wherein said hole transporting layer is 4,4-bis(1-naphthylphenylamino)biphenyl.

21. The method of claim 13, wherein said electron transport layer is 5,5′-bis(dimesitylboryl)2,2′-bithiophene.

22. The method of claim 13, wherein at least one of said transparent electrodes comprises a glass substrate coated with a transparent anode material.

23. The method of claim 22, wherein said transparent anode material is indium tin oxide.

24. The method of claim 13, wherein one of said electrodes comprises a metallic cathode.

25. The method of claim 24, wherein said metallic cathode comprises an alloy of Mg and Ag.
